(19) United States
(12) Patent Application Publication
(10) Pub. No.: US 2018/0276536 A1
(43) Pub. Date: Sep. 27, 2018

(54) REFRACTORY CIRCUIT FOR INTEGRATED ARTIFICIAL NEURON DEVICE

(71) Applicant: STMicroelectronics SA, Montrouge (FR)

(72) Inventors: Philippe Galy, Le Touvet (FR); Thomas Bedecarrats, Saint Martin D'heres (FR)

(73) Assignee: STMicroelectronics SA, Montrouge (FR)

(21) Appl. No.: 15/697,598

(22) Filed: Sep. 7, 2017

(30) Foreign Application Priority Data
Mar. 23, 2017 (FR) 1752384

(51) Int. Cl. G06N 3/063; G06N 3/04; G11C 11/54

(52) U.S. Cl. CPC G06N 3/063; G11C 11/54; G06N 3/049

(57) ABSTRACT

An integrated artificial neuron device includes a refractory circuit configured to inhibit signal integration for an inhibition duration after delivery of an output signal. The refractory circuit includes a first MOS transistor coupled between an input node and a reference node and having a gate connected to the output node by a second MOS transistor having a first electrode coupled to the supply node and a gate coupled to the output node. The refractory circuit further includes a resistive-capacitive circuit coupled between the supply node, the reference node and the gate of the second MOS transistor. An inhibition duration depends on a time constant of the resistive-capacitive circuit.

### PRIORITY CLAIM

This application claims the priority benefit of French Application for Patent No. 1752384, filed on Mar. 23, 2017, the disclosure of which is hereby incorporated by reference in its entirety to the maximum extent allowable by law.

### TECHNICAL FIELD

Embodiments relate to artificial intelligence and, in particular, to the creation of networks of neurons in the context of what is known to those skilled in the art as ‘deep learning’. More precisely, embodiments relate to integrated electronic circuits that simulate the behavior of neurons and, more particularly, to the structure of the refractory circuits of such circuits.

### BACKGROUND

A biological neuron comprises a plurality of parts including, in particular: one or more dendrites that deliver(s) an electrical input signal; the body of the neuron or soma which accumulates the input signal in the form of a potential difference between the interior and the exterior of its membrane; and an axon configured to deliver an output signal or action potential when the voltage between the exterior and the interior of the membrane reaches a certain threshold. In a biological neuron, electrical leakages occur through the membrane if electrical equilibrium is not achieved between the interior and the exterior of the membrane.

An artificial neuron should mimic the operation of the biological neuron and thus be capable of receiving an input signal, of integrating this input signal, and, when the integrated signal reaches a threshold, of emitting an output signal in the form of one or more voltage spikes.

In the field of networks of artificial neurons, the acronym LIF (‘Leaky Integrate-and-Fire’) denotes a simple behavioral model of the artificial neuron in which the artificial neuron receives and accumulates an input signal until a threshold value is exceeded, beyond which threshold value the artificial neuron emits an output signal.

This model takes into account, in particular, the electrical leakages of the neuron through the membrane of the neuron.

The neuron may either receive a series of successive current spikes until an output current spike is generated, or receive a continuous signal at the input and generate a train of current spikes at the output.

It has moreover been observed that neurons have what is termed a refractory period, or inhibition period, immediately after the delivery of an action potential by the axon, during which the neuron is inhibited.

This refractory or inhibition period should thus be reproduced in the artificial neuron in order to get as close as possible to the operation of a biological neuron.

Solutions exist for the creation of artificial neurons in accordance with the LIF model and that make it possible to implement a refractory period which include, for example, several tens of components of large size.

Applications in the field of artificial intelligence, such as for example, but without limitation, the simulation of brain activity, require the creation of networks including a very large number of artificial neurons, typically of the order of one billion. It would thus be very advantageous to use integrated circuits of reduced size.

Solutions exist that use neurons of more reduced sizes and that make it possible to achieve higher operating speeds, but these solutions require the implementation of specific manufacturing methods.

### SUMMARY

In an embodiment, what is proposed is an artificial neuron enabling the implementation of a refractory period and having a limited refractory circuit surface area, where such an artificial neuron can advantageously be produced using conventional CMOS manufacturing methods.

According to one aspect, an integrated artificial neuron device includes an input node configured to receive at least one input signal, an output node configured to deliver at least one output signal, a reference node configured to deliver at least one reference signal, a supply node configured to receive a supply voltage, an integrator circuit configured to receive and integrate said at least one input signal and deliver an integrated signal, a generator circuit configured to receive the integrated signal and, when the integrated signal exceeds a threshold, deliver the output signal.

The device further includes a refractory circuit configured to inhibit the integrator circuit for an inhibition duration after said delivery of said at least one output signal by the generator circuit, the refractory circuit including a first MOS transistor, having a first electrode that is coupled to the input node, a second electrode that is coupled to the reference node, and a gate that is connected to said output node by means of a second MOS transistor. The second MOS transistor has a first electrode that is coupled to said supply node, a second electrode that is coupled to the gate of the first MOS transistor, and a gate that is coupled to the output node. The refractory circuit further includes a resistive-capacitive circuit coupled between the supply node, the reference node and the gate of the second MOS transistor, said inhibition duration depending on a time constant of said resistive-capacitive circuit.

The neuron device including a refractory circuit therefore has a behavior even closer to that of a biological neuron.

Furthermore, the use of a reduced number of components makes possible a reduced surface area of the refractory circuit.

The resistive-capacitive circuit may include a capacitor having a first electrode that is coupled between said supply node and the gate of the first MOS transistor, and a resistor that is coupled between the gate of the second MOS transistor and the reference node.

The capacitor is advantageously an MOS capacitor.

According to another aspect, what is proposed is an integrated circuit comprising a network of artificial neurons including a plurality of devices such as those described previously.

### BRIEF DESCRIPTION OF THE DRAWINGS

Other advantages and features of the invention will become apparent upon examining the detailed description of completely non-limiting embodiments and the appended drawings, in which:

FIG. 1 schematically illustrates from an electrical point of view an integrated artificial neuron device; and

FIG. 2 illustrates an integrated circuit including a network of artificial neurons as shown in FIG. 1.

### DETAILED DESCRIPTION

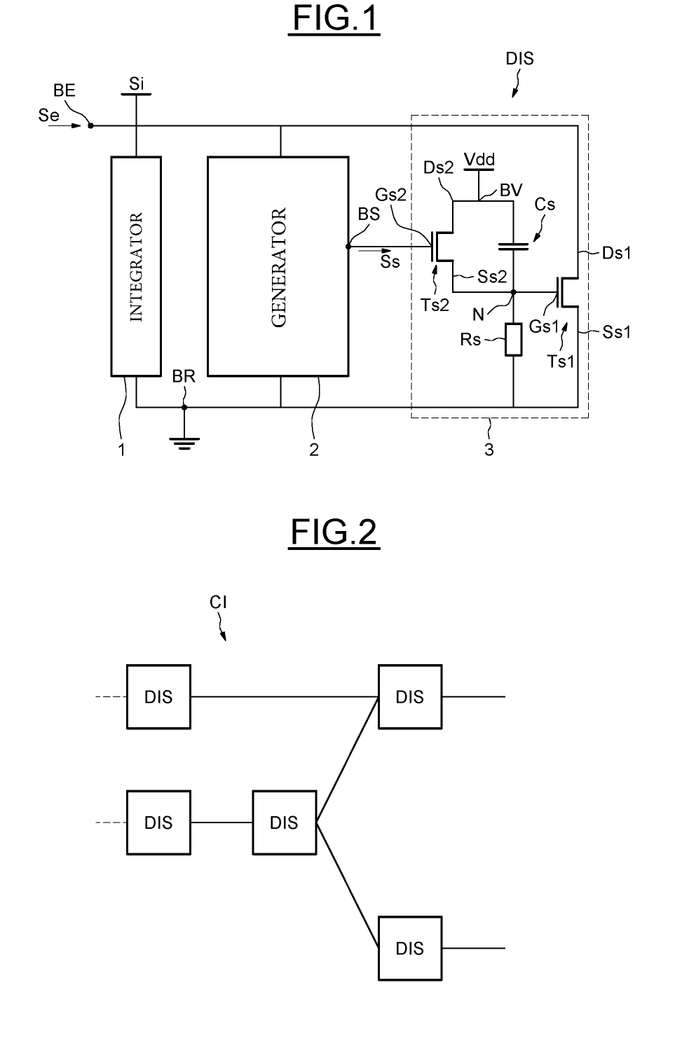

FIG. 1 illustrates, schematically and from an electrical point of view, an integrated artificial neuron device DIS, produced in and on a semiconductor substrate that may be either a bulk substrate or a substrate of silicon-on-insulator type and configured in particular to implement the LIF neuron model.

The operation of the neuron device DIS in this case is therefore analogous to that of a biological neuron.

The device DIS includes an input node BE, configured to receive an input signal Se, an output node BS, configured to deliver an output signal Ss, and a reference node BR configured to receive a reference voltage, in this case ground for example.

The input signal may come from a single source or else be the combination of a plurality of different signals originating from different sources at the node BE.

The device DIS also includes an integrator circuit 1, configured to receive and integrate the input signal Se and to deliver an integrated input signal Si, and a generator circuit 2, configured to deliver the output signal Ss when the integrated signal reaches a threshold (or ‘triggering threshold’).

The integrator circuit 1 and the generator circuit 2 may each include one or more components that may be arranged in accordance with any structure from the prior art, such as for example that described in:

Xinyu Wu,et al., “A CMOS spiking neuron for dense memristor-synapse connectivity for brain-inspired computing,” 2015 International Joint Conference on Neural Networks (IJCNN), Killarney, 2015, pp. 1-6, doi: 10.1109/IJCNN.2015.7280819” (incorporated by reference), or

Indiveri G., et al. “Neuromorphic silicon neuron circuits”, Front. Neurosci. 5:73. 10.3389/fnins.2011 (incorporated by reference), or

French Application for Patent No. 1752383 filed Mar. 23, 2107 (incorporated by reference).

The neuron device DIS further includes a refractory circuit 3, configured to inhibit the integrator circuit 1 for an inhibition period, and a supply node BV configured to receive a supply voltage Vdd, for example a voltage of one volt in this case.

Specifically, it has been observed that biological neurons are inhibited for a period following the delivery of an action potential by the axon of the neuron.

The aim of this refractory circuit 3 is therefore to bring the operation of the neuron device DIS even closer still to the operation of a biological neuron.

The refractory circuit 3 includes a first transistor Ts1 having a first electrode, in this case the drain Ds1, that is coupled to the input node, and having a second electrode, in this case the source Ss1, that is coupled to the reference node.

The gate Gs1 of the first transistor Ts1 is coupled to a common node N.

A second transistor Ts2 has a gate that is coupled to the output node BS, a first electrode, in this case the drain Ds2, that is coupled to the supply node BV, and a second electrode, in this case the source Ss2, that is coupled to the common node N.

Depending on the structure chosen for the generator circuit 2, the value of the voltage Ss (output signal) may be different. Also, depending on the case, the gate of the transistor Ts2 may be coupled directly to the node Bs or else indirectly coupled thereto by means of a conventional voltage adjustment circuit, in such a way that the characteristics of the output signal Ss are compatible with those of the transistor Ts2.

A capacitor Cs is coupled between the supply node BV and the common node N. The capacitor Cs is in this case an MOS capacitor having, for example, a surface area of one square micrometer.

A resistor Rs, for example in this case a resistor of one gigaohm that can be created in practice by an MOS transistor in the ON state, is coupled between the common node N and the reference node BR.

Thus, in operation, before the appearance of a voltage spike on the output node, the capacitor Cs is charged and the voltage across its nodes is equal to the voltage Vdd.

The potential of the common node N is therefore zero, and the gate of the first transistor Ts1 is not biased.

In the presence of a current spike on the output node, the gate Gs2 of the second transistor biases and the second transistor Ts2 becomes conductive.

The gate of the first transistor Ts1 is therefore biased at the voltage Vdd by means of the second transistor Ts2, and the first transistor Ts1 therefore becomes conductive, thus short-circuiting the capacitor Cs.

The potential of the common node N, and therefore the gate Gs1 of the first transistor Ts1, is biased at the supply voltage Vdd, and the first transistor Ts1 becomes conductive, thus short-circuiting the integrator circuit 1.

Once the current spike on the output node has passed, the second transistor Ts2 circuits again, the voltage across the nodes of the capacitor Cs increases progressively, and the potential of the common node therefore decreases progressively until reaching a zero value when the capacitor is completely charged.

When the potential of the common node reaches a value lower than the triggering threshold of the first transistor, the first transistor circuits again.

The inhibition of the integrator circuit by the refractory circuit thus takes place for an inhibition duration that depends on the charging speed of the capacitor Cs through the resistor Rs.

The inhibition duration therefore depends on the time constant of the resistive-capacitive circuit including the resistor Rs and the capacitor Cs.

The structure of such a refractory circuit is advantageous with respect to the refractory circuits of the prior art in that it has a reduced number of components, and as a result makes it possible to obtain a refractory circuit of which the surface area is less than two square micrometers. Thus, by way of indication, for twenty-eight nanometer CMOS technology, the surface area of the refractory circuit is of the order of two square micrometers.

According to one embodiment illustrated in FIG. 2, it is possible to have an integrated circuit CI including a network of artificial neurons, including a plurality of neuron devices according to one or more of the embodiments described previously in connection with FIG. 1, coupled to one another by means of their input or output node.

1. An integrated artificial neuron device, comprising:
an input node configured to receive at least one input signal,
an output node configured to deliver at least one output signal,
a reference node configured to receive a reference voltage,
a supply node configured to receive a supply voltage,
an integrator circuit configured to receive and integrate said at least one input signal and deliver an integrated signal,
a generator circuit configured to receive the integrated signal and, when the integrated signal exceeds a threshold, deliver the output signal, and
a refractory circuit configured to inhibit the integrator circuit for an inhibition duration after said delivery of said at least one output signal by the generator circuit, the refractory circuit including a first MOS transistor having a first electrode that is coupled to the input node, a second electrode that is coupled to the reference node, and a gate that is connected to said output node by a second MOS transistor having a first electrode that is coupled to said supply node, a second electrode that is coupled to the gate of the first MOS transistor, and a gate that is coupled to the output node,
wherein the refractory circuit further includes a resistive-capacitive circuit coupled between the supply node, the reference node and the gate of the second MOS transistor, said inhibition duration depending on the a constant of said resistive-capacitive circuit.

2. The device according to claim 1, wherein the resistive-capacitive circuit includes a capacitor coupled between said supply node and the gate of the first MOS transistor, and a resistor coupled between the gate of the second MOS transistor and the reference node.

3. The device according to claim 2, wherein the capacitor is a CMOS capacitor.

4. An integrated circuit comprising a network of connected artificial neurons, wherein each artificial neuron comprises:
an input node configured to receive at least one input signal,
an output node configured to deliver at least one output signal,
a reference node configured to receive a reference voltage,
a supply node configured to receive a supply voltage,
an integrator circuit configured to receive and integrate said at least one input signal and deliver an integrated signal,
a generator circuit configured to receive the integrated signal and, when the integrated signal exceeds a threshold, deliver the output signal, and
a refractory circuit configured to inhibit the integrator circuit for an inhibition duration after said delivery of said at least one output signal by the generator circuit, the refractory circuit including a first MOS transistor having a first electrode that is coupled to the input node, a second electrode that is coupled to the reference node, and a gate that is connected to said output node by a second MOS transistor having a first electrode that is coupled to said supply node, a second electrode that is coupled to the gate of the first MOS transistor, and a gate that is coupled to the output node,
wherein the refractory circuit further includes a resistive-capacitive circuit coupled between the supply node, the reference node and the gate of the second MOS transistor, said inhibition duration depending on the a constant of said resistive-capacitive circuit.

5. The integrated circuit according to claim 4, wherein the resistive-capacitive circuit includes a capacitor coupled between said supply node and the gate of the first MOS transistor, and a resistor coupled between the gate of the second MOS transistor and the reference node.

6. The integrated circuit according to claim 5, wherein the capacitor is a CMOS capacitor.
